(19) United States
(12) Patent Application Publication
(10) Pub. No.: US 2020/0302858 A1
(43) Pub. Date: Sep. 24, 2020

(54) CONDUCTIVE SUBSTRATE OF A DISPLAY DEVICE

(71) Applicant: XINCHEN TECHNOLOGY CO., LTD., Taichung City (TW)

(72) Inventors: WEN-CHANG FAN, Hsinchu County (TW); CHIA-PIN WANG, Hsinchu County (TW); BO-SHENG LU, Hsinchu County (TW)

(21) Appl. No.: 16/824,922

(22) Filed: Mar. 20, 2020

Related U.S. Application Data
(60) Provisional application No. 62/821,640, filed on Mar. 21, 2019.

(30) Foreign Application Priority Data
Aug. 11, 2019 (TW) 108128442

(51) Int. Cl. G09G 3/32; H01L 33/62; H01L 25/075

(52) U.S. Cl. CPC G09G 3/32; H01L 33/62; G09G 2310/08; G09G 2310/0275; H01L 25/0753

(57) ABSTRACT

A conductive substrate of a display device has an electrically insulating substrate and a plurality of rows of electrical pin connecting areas, a plurality of rows of patterned input voltage lines and a plurality of rows of patterned grounded lines formed on the electrically insulated substrate. Each of the rows of the electrical pin connecting areas includes a plurality of electrical pin connecting areas electrically isolated and spaced from each other in a line. The rows of the patterned input voltage lines are respectively adjacent to the rows of the electrical pin connecting areas, and the rows of the patterned grounded lines are respectively adjacent to the rows of the electrical pin connecting areas. Besides, two opposite sides of at least one row of the patterned input voltage lines are respectively electrically connected with the input voltage pin contacts of two neighboring rows of the electrical pin connecting areas while two opposite sides of at least one row of the patterned grounded lines are respectively electrically connected with the grounded pin contacts of two neighboring rows of the electrical pin connecting areas.

### CROSS-REFERENCE TO RELATED APPLICATIONS

The present application claims the benefit of U.S. provisional application Ser. No. 62/821,640 filed on Mar. 21, 2019 and Taiwan application Ser. No. 108128442 filed on Aug. 11, 2019 which are incorporated herein by reference.

### TECHNICAL FIELD

The present application relates to a conductive substrate, and more particularly to a conductive substrate of a display device.

### BACKGROUND

Light emitting diode (LED) is an electronic component with illuminating material made of semiconductors. Compared with incandescent lamps and cold cathode fluorescent lamps, a LED has advantages of power saving, eco-friendliness, long life span, small volume and fast response. The mature development of using LEDs as spontaneous emitting light sources in the display technology field enables the replacement of the mainstreamed LCD display devices by the flattening, thinning, and lightening LED display devices. On the other hand, an LED device is also becoming a large-size device and aims to be a new favorite in the multimedia information display field.

To light up every LED chip in the LED chip array of an LED display device, there must be good conductivity between the substrate carrying the LED chip array and the LED chip array. In addition, the substrate carrying the LED chip array must have high thermal conductivity such that the operation of each LED chip in the LED chip array can last for a long time. On the other hand, an LED display device also needs good transparency in addition to that the conductive wires on the substrate carrying the LED chip array is well produced to cope with a variety of wiring demands and rapidly completed when the lighting-up of each LED chip in the LED chip array is required to present various display effects as demanded. Therefore, the proposed invention is to solve the technic problem of making the substrate carrying the LED chip have high electrical conductivity, high thermal conductivity, and high transparency, and can meet the requirements of various applications.

### SUMMARY

In view of the above-mentioned issues, the present application proposed a conductive substrate of a display device.

In one embodiment, the proposed conductive substrate of a display device includes an electrically insulating substrate, a plurality of rows of electrical pin connecting areas, a plurality of rows of patterned input voltage lines, and a plurality of rows of patterned grounded lines. The rows of the electrical pin connecting areas are disposed on the electrically insulating substrate, each of the rows has a plurality of electrical pin connecting areas that are electrically isolated and spaced from each other in a line, each of the electrical pin connecting areas includes at least an input voltage pin contact and a grounded pin contact respectively served to electrically connect an input voltage pin and a grounded pin of a light emitting source. The rows of the patterned input voltage lines are electrically connected with and spaced from each other and disposed on the electrically insulating substrate, and the rows of the patterned input voltage lines are respectively adjacent to the rows of the electrical pin connecting areas. The rows of the patterned grounded lines are electrically connected with and spaced from each other and disposed on the electrically insulating substrate, and the rows of the patterned grounded lines are respectively adjacent to the rows of the electrical pin connecting areas. In addition, two opposite sides of at least one of the rows of the patterned input voltage lines are respectively electrically connected with the input voltage pin contacts of two neighboring rows of the electrical pin connecting areas while two opposite sides of at least one of the rows of the patterned grounded lines are respectively electrically connected with the grounded pin contacts of the two neighboring rows of the electrical pin connecting areas.

In one embodiment, the input voltage pin contact and the grounded pin contact of each of the electrical pin connecting areas are diagonally disposed, the input voltage pin contacts of the two neighboring rows of the electrical pin connecting areas are located toward opposite directions, and the grounded pin contacts of the two neighboring rows of the electrical pin connecting areas are located toward opposite directions.

In one embodiment, each of the rows of the patterned input voltage lines has a plurality of parallel connected wires respectively extending toward the neighboring rows of the electrical pin connecting areas and respectively connecting the input voltage pin contacts of the corresponding electrical pin connecting areas of the neighboring rows of the electrical connecting areas; or each of the rows of the patterned grounded lines has a plurality of parallel connected wires respectively extending toward the neighboring rows of the electrical pin connecting areas and respectively connecting the grounded pin contacts of the corresponding electrical pin connecting areas of the neighboring rows of the electrical pin connecting areas.

In one embodiment, each of the rows of the patterned input voltage lines has at least one parallel wire extending in parallel with the row direction of the neighboring row of the electrical pin connecting areas and serially connecting the input voltage pin contacts of the electrical pin connecting areas of the neighboring row of the electrical pin connecting areas; or each of the rows of the patterned grounded lines has at least one parallel wire extending in parallel with the row direction of the neighboring row of the electrical pin connecting areas and serially connecting the grounded pin contacts of the electrical pin connecting areas of the neighboring row of the electrical pin connecting areas.

In one embodiment, at least one of the rows of the patterned input voltage lines or at least one of the rows of the patterned grounded lines has a plurality of wires constituting a patterned mesh lines including a plurality of lattices.

In one embodiment, the rows of the patterned input voltage lines and the rows of the patterned grounded lines are on the same plane and disposed in an interdigitated manner.

In one embodiment, each of the electrical pin connecting areas further includes a data signal input pin contact, a data signal output pin contact, a clock signal input pin contact, and a clock signal output pin contact respectively used for electrical connection with a data signal input pin, a data signal output pin, a clock signal input pin, and a clock signal output pin of the light emitting source, wherein the data signal input pin contact and the clock signal input pin contact of one of the electrical pin connecting areas are respectively electrically connected to the data signal output pin contact and the clock signal output pin contact of the neighboring electrical pin connecting area.

In one embodiment, the conductive substrate of the display device further includes a plurality of transparent conductive layer regions disposed to be electrically isolated from each other on the electrically insulating substrate, wherein a first transparent conductive layer region of the transparent conductive layer regions electrically connects the data signal input pin contact of the electrical pin connecting area with the data signal output pin contact of the neighboring electrical pin connecting area, or a second transparent conductive layer region of the transparent conductive layer regions electrically connects the clock signal input pin contact of the electrical pin connecting area with the clock signal output pin contact of the neighboring electrical pin connecting area.

In one embodiment, one of the rows of the patterned input voltage lines or one of the rows of the patterned grounded lines has a main wire and a plurality of parallel connected wires extending from the main wire, the main wire is disposed between the two neighboring rows of the electrical pin connecting areas while the parallel connected wires extend toward the neighboring row of the electrical pin connecting areas and respectively electrically connect the input voltage pin contacts or the grounded pin contacts of the corresponding electrical pin connecting areas in the neighboring row of the electrical pin connecting areas.

In one embodiment, the input voltage pin and the grounded pin of the light emitting source are disposed on the same side of an emitting surface of the light emitting source.

In one embodiment, the proposed conductive substrate of the display device further has a plurality of transparent conductive layer regions disposed to be electrically isolated from each other on the electrically insulating substrate, wherein the input voltage pin contacts and the grounded pin contacts are respectively disposed on the transparent conductive layer regions and in touch with the transparent conductive layer regions.

In an embodiment, the rows of the patterned input voltage lines are commonly electrically connected to a first wire connecting region, the rows of the patterned grounded lines are commonly electrically connected to a second wire connecting region, and the first wire connecting region and the second wire connecting region are disposed on the same side of the electrically insulating substrate.

In one embodiment, the rows of the patterned input voltage lines and the rows of the patterned grounded lines include conductive powder particles made of a substance selected from a group consisting of copper, silver, nickel, silver-coated copper, and carbon and with particle size of less than 200 um.

Compared with the conventional LED conductive substrate, the proposed conductive substrate of the display device according to the embodiments of the present invention has patterned conductive lines with high density, high electrical conductivity and high thermal conductivity. These patterned conductive lines include the rows of electrical pin connecting areas, the rows of patterned input voltage lines, and the rows of patterned grounded lines. The input voltage pin contacts of the electrical pin connecting areas in the same row are all connected to a parallel wire or a plurality of parallel wires of a neighboring row of the patterned input voltage lines, while the grounded pin contacts of the electrical pin connecting areas in the same row are all connected to a parallel wire or a plurality of parallel wires of a neighboring row of the patterned grounded lines. In addition, the input voltage pin contacts in the electrical pin connecting areas of two neighboring rows can be commonly connected to a row of patterned input voltage lines disposed between the two neighboring rows of the electrical pin connecting areas, while the grounded pin contacts in the electrical pin connecting areas of the two neighboring rows can be commonly connected to a row of the patterned grounded lines disposed between the two neighboring rows of the electrical pin connecting areas. In this way, the proportion of the areas on the conductive substrate occupied by the conductive lines extending from the pin contacts of the rows of the electrical pin connecting areas to the peripheral of the conductive substrate is reduced, and which further increases the transparency of the display device. Therefore, the patterning process simplifies the manufacturing complexity of the conductive substrate of the display device.

Various other objects, advantages and features of the present invention will become readily apparent from the ensuing detailed description accompanying drawings, and the novel features will be particularly pointed out in the appended claims.

### BRIEF DESCRIPTION OF DRAWINGS

The following detailed descriptions, given by way of example, and not intended to limit the present invention solely thereto, will be best understood in conjunction with the accompanying figures:

FIG. 1 is a plan view schematically showing a conductive substrate of a display device according to a first embodiment of the present invention.

FIG. 2A is a plan view schematically showing a row of electrical pin connecting areas on the conductive substrate of the display device of FIG. 1.

FIG. 2B is a plan view schematically showing the arrangement of rows of patterned input voltage lines, rows of patterned grounded lines, and rows of electrical pin connecting areas on the conductive substrate of the display device of FIG. 1.

FIG. 2C is a plan view schematically showing a row of the electrical pin connecting areas on a conductive substrate of a display device according to a second embodiment of the present invention.

FIG. 2D is a plan view schematically showing a row of the electrical pin connecting areas on a conductive substrate of a display device according to a third embodiment of the present invention.

FIG. 3A is a plan view schematically showing that the pins of the light source to be mounted onto the conductive substrate of the display device of FIG. 1 are disposed on the same side of the back surface of the light source according to one embodiment of the present invention.

FIG. 3B is a plan view schematically showing that the pins of the light emitting source to be mounted onto the conductive substrate of the display device of FIG. 1 are disposed on the same side of the light emitting surface of the light emitting source according to another embodiment of the present invention.

FIG. 4 is a plan view schematically showing rows of the patterned input voltage lines and rows of the patterned grounded lines on a conductive substrate of a display device according to a fourth embodiment of the present invention.

FIG. 5A is a plan view schematically showing a part of a row of the patterned input voltage lines on a conductive substrate of a display device according to a fifth embodiment of the present invention.

FIG. 5B is a plan view schematically showing a part of a row of the patterned grounded lines on a conductive substrate of a display device according to a fifth embodiment of the present invention.

FIG. 6 is a cross-sectional view showing a structure of the electrical pin connecting areas on a conductive substrate of a display device according to a sixth embodiment of the present invention.

FIG. 7 is a plan view schematically showing the arrangement of rows of the patterned input voltage lines, rows of the patterned grounded lines, and rows of the electrical pin connecting areas on a conductive substrate of a display device according to a seventh embodiment of the present invention.

FIG. 8 is a plan view schematically showing rows of the patterned input voltage lines and rows of the grounded lines on a conductive substrate of a display device according to an eighth embodiment of the present invention.

### DETAILED DESCRIPTION OF THE EMBODIMENTS

The present invention discloses a conductive substrate of a display device. The accompanied drawings are intended to express the features relating to the present invention and give meanings that can be easily understood. The drawings may not be plotted in actual scale and do not limit the present invention. In addition, the technical terms described in the following text may not have the same meanings as that of the common terms in the technical field, and the meanings described in the text for the technical terms shall prevail.

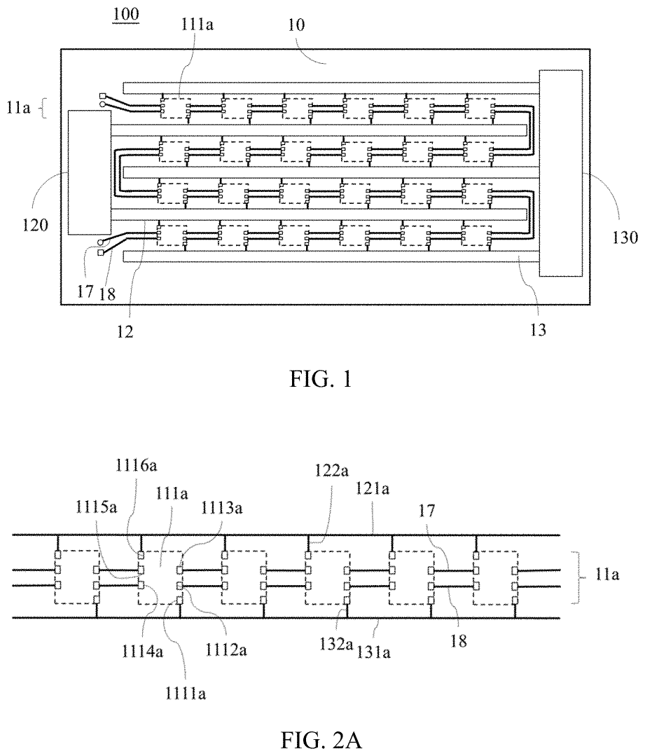

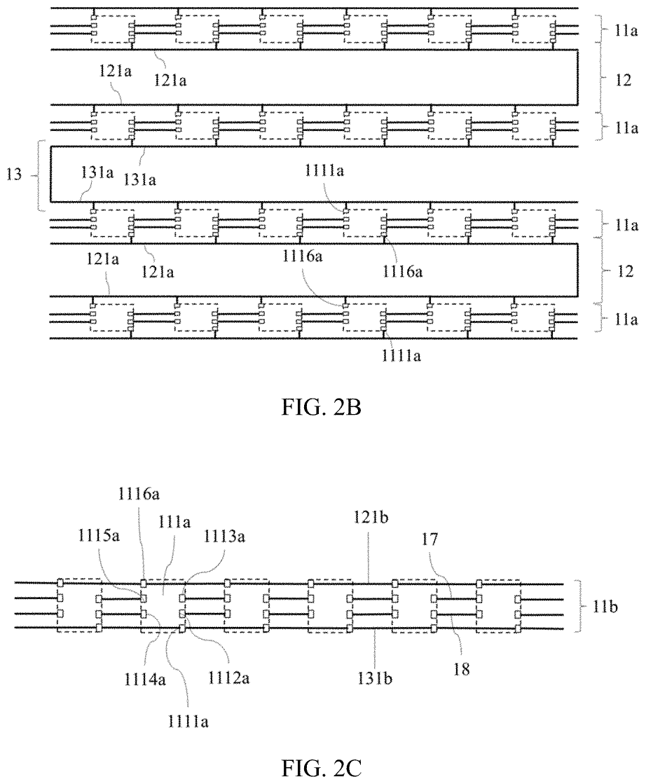

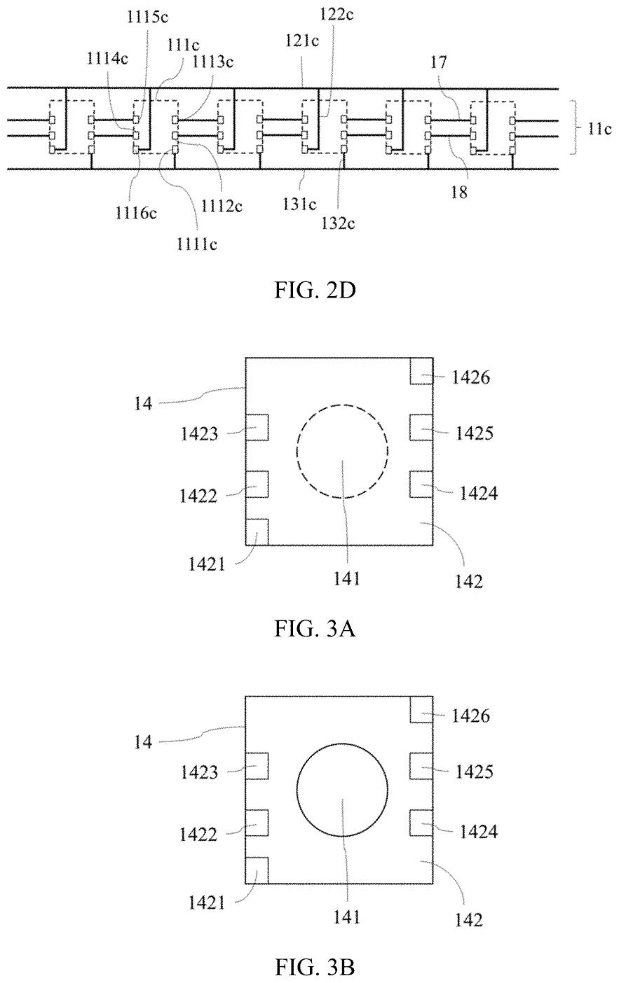

FIG. 1 is a plan view schematically showing a conductive substrate of a display device according to a first embodiment of the present invention. FIG. 2A is a plan view schematically showing a row of electrical pin connecting areas on the conductive substrate of the display device of FIG. 1. FIG. 2B is a plan view schematically showing the arrangement of rows of patterned input voltage lines, rows of patterned grounded lines, and rows of electrical pin connecting areas on the conductive substrate of the display device of FIG. 1. FIG. 3A is a plan view schematically showing that the pins of the light source to be mounted onto the conductive substrate of the display device of FIG. 1 are disposed on the same side of the back surface of the light source according to one embodiment of the present invention. FIG. 3B is a plan view schematically showing that the pins of the light emitting source to be mounted onto the conductive substrate of the display device of FIG. 1 are disposed on the same side of the light emitting surface of the light emitting source according to another embodiment of the present invention.

As shown in FIGS. 1, 2A, and 2B, in one embodiment, a conductive substrate 100 of a display device has an electrically insulating substrate 10, more than two rows 11a of electrical pin connecting areas, more than two rows 12 of patterned input voltage lines and more than two rows 13 of patterned grounded lines. The electrically insulating substrate 10 is, for example, a transparent electrically insulating substrate to constitute a transparent display device. The material of the electrically insulating substrate 10 is, for example, glass, ceramic, aluminum nitride ceramic, polycarbonate, polyethylene terephthalate, polyimide or cyclic olefin copolymer. The number of the rows 11a of the electrical pin connecting areas, the rows 12 of the patterned input voltage line and the rows 13 of the patterned grounded line are only exemplified, and the actual number thereof depends on the size of the electrically insulating substrate 10 and the maximum number of rows that can be accommodated in the electrically insulating substrate 10. The invention is not limited thereto.

As shown in FIGS. 1, 2A and 2B, in a first embodiment, the rows 11a of the electrical pin connecting areas are disposed on the electrically insulating substrate 10 and in touch with the electrically insulating substrate 10, each of the rows 11a of the electrical pin connecting areas has a plurality of electrical pin connecting areas 111a that are electrically isolated and spaced from each other in a line. Each of the electrical pin connecting areas 111a includes a plurality of pin contacts 1111a, 1112a, 1113a, 1114a, 1115a and 1116a. The pin contacts 1111a, 1112a, 1113a, 1114a, 1115a and 1116a are respectively served to electrically connect a plurality of pins 1421, 1422, 1423, 1424, 1425 and 1426 of the light emitting source 14 shown in FIG. 3A. In one embodiment, the pin contacts 1111a, 1112a, 1113a, 1114a, 1115a and 1116a are respectively a grounded pin 1111a, a clock signal output pin contact 1112a, a data signal output pin contact 1113a, a clock signal input pin contact 1114a, a data signal input pin contact 1115a and a input voltage pin contact 1116a. The input voltage pin contact 1116a and the grounded pin contact 1111a are respectively served to electrically connect an input voltage pin 1421 and a ground pin 1426 of the light emitting source 14 shown in FIG. 3A, and the data signal input pin contact 1115a, the data signal output pin contact 1113a, the clock signal input pin contact 1114a and the clock signal output pin contact 1112a are respectively served to electrically connect a data signal input pin 1425, a data signal output pin 1423, a clock signal input pin 1424 and a clock signal output pin 1422 of the light emitting source 14 shown in FIG. 3A. The pin contacts 1111a, 1112a, 1113, 1114a, 1115a and 1116a of each electrical pin connecting area 111a are respectively connected with a parallel connected wire 132a, a clock signal input line 18, a data signal input line 17, a clock signal input line 18, a data signal input line 17 and a parallel connected wire 122a. As shown in FIG. 3A, each light emitting source 14 has a light emitting surface 141. The pins 1421, 1422, 1423, 1424, 1425 and 1426 of each light emitting source 14 can be disposed on the same side of a back surface 142 of the light emitting source 14 opposite to the light emitting surface 141 of the light emitting source 14. In another embodiment, as shown in FIG. 3B, the pins 1421, 1422, 1423, 1424, 1425 and 1426 of each light emitting source 14 can be disposed on the same side of the light emitting surface 141. When the electrically insulating substrate 10 is transparent, by disposing the pins 1421, 1422, 1423, 1424, 1425 and 1426 of the light emitting source 14 on the same side of the light emitting surface 141 and electrically coupling the light emitting source 14 to the conductive substrate 100 of the display device, the light emitting surface 141 of the light emitting source 14 is enabled to face and close to the electrically insulating substrate 10, which reduces the chance that a reflected light of the emitting light of the light emitting source 14 by the electrically insulating substrate 10 enters a user's eyes. In one embodiment, the light emitting source 14 is, for example, an LED lamp bead, and the pins 1422, 1423, 1424 and 1425 of each light emitting source 14 are respectively a clock signal output pin 1422, a data signal output pin 1423, a clock signal input pin 1424 and a data signal input pin 1425.

As shown in FIGS. 1, 2A and 2B, the rows 12 of the patterned input voltage lines are electrically connected with each other through a first wire connecting region 120 spaced from each other and disposed on the electrically insulating substrate 10. The rows 12 of the patterned input voltage lines are commonly electrically connected to the first wire connecting region 120 to form a first comb-like structure. The rows 12 of the patterned input voltage lines are respectively adjacent to the rows 11a of the electrical pin connecting areas. Each of the rows 12 of the patterned input voltage lines has a plurality of wires including parallel wires 121a and parallel connected wires 122a shown in FIG. 2A. Each of the parallel wires 121a is extending in parallel with the row direction of the neighboring row 11a of the electrical pin connecting areas and serially connecting the input voltage pin contacts 1116a of the electrical pin connecting areas 111a of the neighboring row 11a of the electrical pin connecting areas. The parallel connected wires 122a are extending toward the neighboring row 11a of the electrical pin connecting areas, for example, along the direction perpendicular to the row direction of the neighboring row 11a of the electrical pin connecting areas, and respectively directly connecting the input voltage pin contacts 1116a of the corresponding electrical pin connecting areas 111a of the neighboring row 11a of the electrical pin connecting areas. On the other hand, the rows 13 of the patterned grounded lines are electrically connected with each other through a second wire connecting region 130 and spaced from each other and disposed on the electrically insulating substrate 10. The rows 13 of the patterned grounded lines are commonly electrically connected to the second wire connecting region 130 to form a second comb-like structure. The rows 13 of the patterned grounded lines are respectively adjacent to the rows 11a of the electrical pin connecting areas. Each of the rows 13 of the patterned grounded lines has a plurality of wires including parallel wires 131a and parallel connected wires 132a shown in FIG. 2A. Each of the parallel wires 131a is extending in parallel with the row direction of the neighboring row 11a of the electrical pin connecting areas and serially connecting the grounded pin contact 1111a of the electrical pin connecting areas 111a in the neighboring row 11a of the electrical pin connecting areas. The parallel connected wires 132a are respectively extending toward the neighboring row 11a of the electrical pin connecting areas, for example, along the direction perpendicular to the row direction of the neighboring row 11a of the electrical pin connecting areas, and respectively directly connecting the grounded pin contacts 1111a of the corresponding electrical pin connecting areas 111a of the neighboring row 11a of the electrical pin connecting areas. In one embodiment, the rows 13 of the patterned grounded lines and the rows 12 of the patterned input voltage lines are parallel to each other, on the same plane and disposed in an interdigitated manner so that each of two opposite sides of at least one row of the rows 13 of the patterned grounded lines is adjacent to one row 12 of the patterned input voltage lines. As shown in FIGS. 2A and 2B, two opposite sides of at least one row 12 of the patterned input voltage lines are respectively electrically connected with the input voltage pin contacts 1116a of two neighboring rows 11a of the electrical pin connecting areas while two opposite sides of at least one row 13 of the patterned grounded lines are respectively electrically connected with the grounded pin contacts 1111a of two neighboring rows 11a of electrical pin connecting areas, thereby simplifying the design of the conductive wires and increasing the transparency of the conductive substrate 100 of the display device. In particular, as shown in FIG. 2B, each of two opposite sides of each of the rows 12 of the patterned input voltage lines has a parallel wire 121a. Two parallel wires 121a of the row 12 of the patterned input voltage line are respectively commonly electrically connected to the input voltage pin contacts 1116a of two neighboring rows 11a of the electrical pin connecting areas. Each of two opposite sides of each of the rows 13 of the patterned grounded lines has a parallel wire 131a. Two parallel wires 131a of the row 13 of the patterned grounded line are respectively commonly electrically connected to the grounded pin contacts 1111a of two neighboring rows 11a of electrical pin connecting areas. The two parallel wires 121a disposed on two opposite sides of each of the rows 12 of the patterned input voltage lines are separated by an interval and the space within the interval can accommodate a conductive wire pattern composed of other wires except the parallel wires 121a and the parallel connected wires 122a of the rows 12 of patterned input voltage lines. Similarly, the two parallel wires 131a disposed on two opposite sides of each of the rows 13 of the patterned grounded lines are separated by an interval and the space within the interval can accommodate a conductive wire pattern composed of other wires except the parallel wires 131a and the parallel connected wires 132a of the rows 13 of patterned grounded lines.

As shown in FIGS. 2A and 2B, the two parallel wires 121a on two opposite sides of each of the rows 12 of the patterned input voltage lines are respectively electrically connected with the input voltage pin contacts 1116a of the corresponding electrical pin connecting areas 111a of the neighboring rows 11a of the electrical pin connecting areas through the parallel connected wires 122a, and the two parallel wires 131a on two opposite sides of each of the rows 13 of the patterned grounded lines are respectively electrically connected with the grounded pin contacts 1111a of the corresponding electrical pin connecting areas 111a of the neighboring rows 11a of the electrical pin connecting areas through the parallel connected wires 132a. As shown in FIG. 2B, the input voltage pin contact 1116a and the grounded pin contact 1111a of each of the electrical pin connecting areas 111a are diagonally disposed on two opposite sides of the electrical pin connecting area 111a. In addition, the pin contacts of any of the electrical pin connecting areas 111a and the pin contacts of any of the electrical pin connecting areas 111a of the neighboring row 11a of electrical pin connecting areas are located toward opposite directions. Specifically, the input voltage pin contacts of the two neighboring rows of the electrical pin connecting areas are located toward opposite directions, and the grounded pin contacts of the two neighboring rows of the electrical pin connecting areas are located toward opposite directions. For example, the input voltage pin contact 1116a of the bottom row of electrical pin connecting area 111a is at the upper left corner and the input voltage pin contact 1116a of the neighboring row of electrical pin connecting area 111a is at the lower right corner.

FIG. 2C is a plan view schematically showing a row of the electrical pin connecting areas on a conductive substrate of a display device according to a second embodiment of the present invention. In the second embodiment, the row of the electrical pin connecting areas 11b shown in FIG. 2C replaces the row 11a of the electrical pin connecting areas of the first embodiment. However, each of the rows 11b of the electrical pin connecting areas has the same electrical pin connecting areas 111a and the same pin contacts 1111a, 1112a, 1113a, 1114a, 1115a and 1116a of the electrical pin connecting area 111a as those exemplified in the first embodiment. The input voltage pin contact 1116a and the grounded pin contact 1111a of each of the electrical pin connecting areas 111a are diagonally disposed on two opposite sides and other details are not described herein. The difference from the first embodiment is that the pin contacts 1111a, 1112a, 1113a, 1114a, 1115a and 1116a are respectively electrically connected with the parallel wire 131b, the clock signal input line 18, the data signal input line 17, the clock signal input line 18, the data signal input line 17 and the parallel wire 121b. In the present embodiment, each of the rows 12 of patterned input voltage lines has a plurality of wires including the parallel wires 121b shown in FIG. 2C. Each of the parallel wires 121b is extending in parallel with row direction of neighboring rows 11b of electrical pin connecting areas and serially connecting the input voltage pin contacts 1116a of all the electrical pin connecting areas 111a in one of the neighboring rows 11b of the electrical pin connecting areas. Each of the rows 13 of the patterned grounded lines has a plurality of wires including the parallel wires 131b shown in FIG. 2C. Each of the parallel wires 131b is extending in parallel with the row direction of the neighboring row 11b of the electrical pin connecting areas and serially connecting the grounded pin contacts 1111a of the electrical pin connecting areas 111a in the neighboring row 11b of electrical pin connecting areas. Compared with the first embodiment, the row 12 of the patterned input voltage lines in the present embodiment omits the parallel connected wires 122a shown in FIG. 2A, and the row 13 of the patterned grounded lines omits the parallel connected wires 132a shown in FIG. 2A for further improving the transparency of the entire conductive substrate 100. In addition, similar to that shown in FIG. 2B, each of two opposite sides of each of the rows 12 of the patterned input voltage lines has a parallel wire 121b. Two parallel wires 121b of the row 12 of the patterned input voltage line are respectively commonly electrically connected to the input voltage pin contacts 1116a of two neighboring rows 11a of the electrical pin connecting areas. Each of two opposite sides of each of the rows of the patterned grounded lines 13 has a parallel wire 131b. Two parallel wires 131b of the row 13 of the patterned grounded line are respectively commonly electrically connected to the grounded pin contacts 1111a of two neighboring rows 11a of the electrical pin connecting areas. The pin contacts of any of the electrical pin connecting areas 111a and the pin contacts of any of the electrical pin connecting areas 111a of the neighboring row 11a of electrical pin connecting areas are located toward opposite directions.

FIG. 2D is a plan view schematically showing a row of the electrical pin connecting areas on a conductive substrate of a display device according to a third embodiment of the present invention. In the third embodiment, as shown in FIG. 2D, each of the rows 11c of the electrical pin connecting areas has the same electrical pin connecting areas 111c that are electrically isolated and spaced from each other in a line and the same pin contacts 1111c, 1112c, 1113c, 1114c, 1115c and 1116c of the electrical pin connecting area 111c as those exemplified in the first embodiment. The difference from the first embodiment is that the input voltage pin contact 1116c and the grounded pin contact 1111c of each of the electrical pin connecting areas 111c of each of the rows 11c of the electrical pin connecting areas are respectively disposed on the same side and opposite positions instead of opposite sides and diagonal positions of the electrical pin connecting areas 111c. In addition, the pin contacts 1111c, 1112c, 1113c, 1114c, 1115c, and 1116c of each of the electrical pin connecting areas 111c are respectively electrically connected with the wires 132c, 18, 17, 18, 17, and 122c. Each of the rows 12 of patterned input voltage lines has a plurality of wires including parallel wires 121c and parallel connected wires 122c shown in FIG. 2D. Each of the parallel wires 121c is extending in parallel with the row direction of the neighboring row 11c of the electrical pin connecting areas and serially connecting the input voltage pin contacts 1116c of the electrical pin connecting areas 111c of the neighboring row 11c of the electrical pin connecting areas. Each of the parallel connected wires 122c extends toward neighboring rows 11c of electrical pin connecting areas, for example, along the direction perpendicular to the neighboring row 11c of the electrical pin connecting areas, extends across the middle area of the electrical pin connecting areas 111c, and is directly connected to the input voltage pin contact 1116c of the corresponding electrical pin connecting areas 111c through the curved end, thereby enabling most of the parallel connected wires 122c to be un-exposed in the display device and increasing the transparency of the display device. Each of the rows 13 of the patterned grounded lines has a plurality of wires including parallel wires 131c and parallel connected wires 132c shown in FIG. 2D. Each of the parallel wires 131c extends in parallel with the row direction of the neighboring row 11c of the electrical pin connecting areas and serially connects the grounded pin contact 1111c of the electrical pin connecting areas 111c of the neighboring row 11c of electrical pin connecting areas. Each of the parallel connected wires 132c respectively extends toward the neighboring row 11c of the electrical pin connecting areas, for example, extends along the direction perpendicular to the neighboring row 11c of the electrical pin connecting areas, and respectively connects the grounded pin contacts 1111c of the corresponding electrical pin connecting areas 111c. Compared with the first embodiment, the parallel connected wire 122c of the rows 12 of the patterned input voltage lines in the present embodiment extends in a larger distance inside the electrical pin connecting area 111c than a distance inside the electrical pin connecting area 111a in which the parallel connected wire 122a extends as shown in FIG. 2A. In addition, similar to that shown in FIG. 2B, each of two opposite sides of each of the rows 12 of the patterned input voltage lines has a parallel wire 121c. Two parallel wires 121c of the row 12 of the patterned input voltage line are respectively commonly electrically connected to the input voltage pin contacts 1116c of the two neighboring rows 11c of the electrical pin connecting areas. Each of two opposite sides of each of the rows 13 of the patterned grounded lines has a parallel wire 131c. Two parallel wires 131c of the row 13 of the patterned grounded line are respectively commonly electrically connected to the grounded pin contacts 1111c of two neighboring rows 11c of the electrical pin connecting areas. The pin contacts of any of the electrical pin connecting areas 111c and the pin contacts of any of the electrical pin connecting areas 111c of the neighboring row 11c of the electrical pin connecting areas are located toward opposite directions.

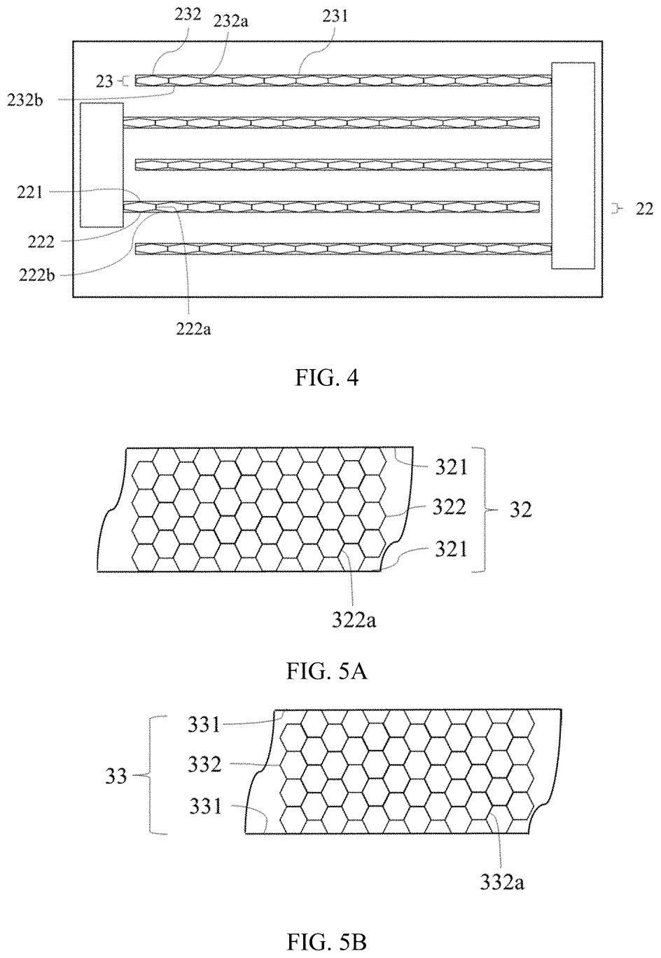

FIG. 4 is a plan view schematically showing rows of the patterned input voltage lines and rows of the patterned grounded lines on a conductive substrate of a display device according to a fourth embodiment of the present invention. As shown in FIG. 4, in another embodiment, a part of the plurality of conductive wires of each of the rows of patterned input voltage lines 22 can constitute a patterned mesh lines including a plurality of lattices 222. The lattices 222 of each of the rows of the patterned input voltage lines 22 are arranged as a left and right connected row, and each of the upper and lower sides of each of the rows of the patterned input voltage lines 22 includes a parallel wire 221. In addition, when the lattice 222 is shaped to be a polygon, for example, a regular hexagon and the two opposite corners of the lattice are respectively connected to the corresponding two parallel wires 221, the line width of the boundary 222a of any lattice 222 extending in a direction perpendicular to the row direction of the row 11a of the electrical pin connecting areas is equal to the line width of the other boundary 222b of the same lattice 222. Similarly, a part of the plurality of conductive wires of each of the rows of the patterned grounded lines 23 can constitute a patterned mesh lines including a plurality of lattices 232. The lattices 232 of each of the rows of the patterned grounded lines 23 are arranged as a left and right connected row, and each of the upper and lower sides of each of the rows of the patterned grounded lines 23 respectively includes a parallel wire 231. In addition, when the lattice 232 is shaped to be a polygon, for example, a regular hexagon and the two opposite corners of the lattice 232 are respectively connected to the corresponding two parallel wires 231, the line width of the boundary 232a of any lattice 232 extending in a direction perpendicular to the row direction of the rows 11a of electrical pin connecting areas is equal to the line width of the other boundary 232b of the same lattice 232. The arrangement of the lattices 222 and 232 contributes to improve the conductivity and heat dissipation. Although the shapes of the lattices 222 and 232 shown in FIG. 4 are regular hexagons to simplify the design of the patterned lines and improve the transparency of the conductive substrate, the invention is not restricted hereto, any other lattice shape that can contribute to improve the conductivity and heat dissipation is within the scope of the present invention. In addition, the number of the lattices 222 and 232 depends on the actual need for the conductivity and heat dissipation of the display device as a whole and is not limited by the illustration shown in FIG. 4.

FIG. 5A is a plan view schematically showing a part of a row of the patterned input voltage lines on a conductive substrate of a display device according to a fifth embodiment of the present invention. FIG. 5B is a plan view schematically showing a part of a row of the patterned grounded lines on a conductive substrate of a display device according to a fifth embodiment of the present invention. As shown in FIG. 5A, in another embodiment, a part of the plurality of conductive wires of each of the rows of the patterned input voltage lines 32 can constitute a patterned mesh lines including a plurality of lattices 322. The lattices 322 of each of the rows of the patterned input voltage lines 32 are arranged as a left and right connected and up and down connected row, and each of the upper and lower sides of each of the rows of the patterned input voltage lines 32 includes a parallel wire 321. In addition, when the lattice 322 is shaped to be a polygon, for example, a regular hexagon, and the lattices 322 on opposite two sides of the connected row are respectively connected to the corresponding parallel wires 321 by a boundary 322a, the line width of each boundary 322a of any lattice 322 is equal to the line width of the parallel wire 321. Similarly, as shown in FIG. 5B, a part of the plurality of conductive wires of each of the rows of the patterned grounded lines 33 can constitute a patterned mesh lines including a plurality of lattices 332. The lattices 332 of each of the rows of the patterned grounded lines 33 are arranged as a left and right connected and up and down connected row, and each of the upper and lower sides of each of the rows of patterned grounded lines 33 respectively includes a parallel wire 331. In addition, when the lattice 332 is shaped to be a polygon, for example, a regular hexagon, and the lattices 332 on opposite two sides of the connected row are respectively connected to the corresponding parallel wires 331 by a boundary 332a, the line width of each boundary 332a of any lattice 332 is equal to the line width of the parallel wire 331. The arrangement of the lattices 322 and 332 contributes to improve the conductivity and heat dissipation. Although the shapes of the lattices 322 and 332 shown in FIGS. 5A and 5B are regular hexagons to simplify the design of the patterned lines and improve the transparency of the conductive substrate, but the invention is not restricted hereto, any other lattice shape that can contribute to improve the conductivity and heat dissipation is within the scope of the present invention. In addition, the number of the lattices 322 and 332 depends on the actual needs for conductivity and heat dissipation of the display device as a whole and is not limited to the number shown in FIGS. 5A and 5B.

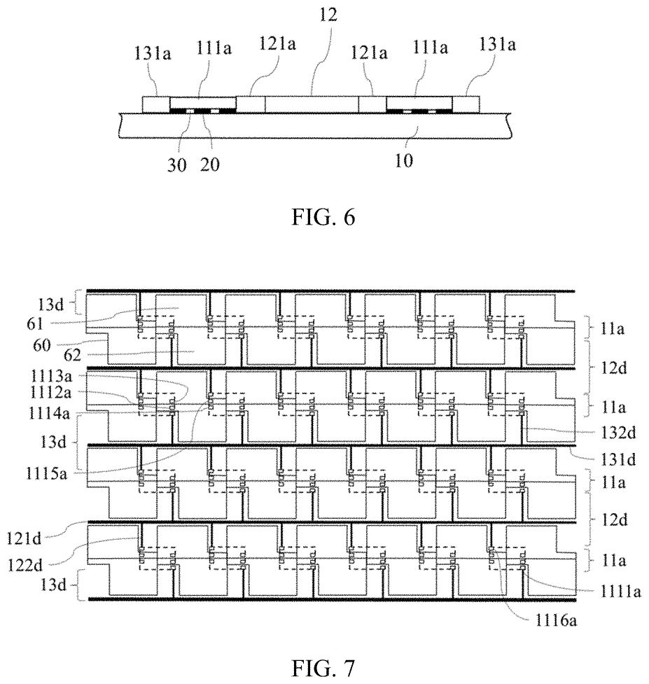

FIG. 6 is a cross-sectional view showing a structure of the electrical pin connecting areas on a conductive substrate of a display device according to a sixth embodiment of the present invention. As shown in FIG. 6, in one embodiment, the electrically insulating substrate 10 includes a plurality of transparent conductive layer regions 20, a plurality of trenches 30 are respectively disposed between the transparent conductive layer regions 20 and electrically isolate the transparent conductive layer regions 20 from each other. Each of the trenches 30 exposes the surface of the electrically insulating substrate 10, and each of the transparent conductive layer regions 20 corresponds to a pin contact 1111a, 1112a, 1113a, 1114a, 1115a or 1116a of one electrical pin connecting area 111a shown in FIG. 2A. In other words, the transparent conductive layer region 20 is in direct touch with the electrically insulating substrate 10, and the pin contacts 1111a, 1112a, 1113a, 1114a, 1115a and 1116a of the electrical pin connecting area 111a are respectively formed on one transparent conductive layer region 20 and in touch with the transparent conductive layer region 20 to improve heat dissipation effect through the transparent conductive layer region 20. The transparent conductive layer region 20 is formed from a film separated by trenches and the film is, for example, an indium tin oxide (ITO) film, a fluorine-doped tin oxide (FTO) film, a zinc oxide (ZnO) film or an aluminum zinc oxide (AZO) film formed by sputtering or evaporating. In another embodiment, without the transparent conductive layer region 20, the pin contacts 1111a, 1112a, 1113a, 1114a, 1115a and 1116a of each of the electrical pin connecting areas 111a can be directly formed on the electrically insulating substrate 10 and in direct touch with the electrically insulating substrate 10. In one embodiment, the material of the pin contacts 1111a, 1112a, 1113a, 1114a, 1115a and 1116a is, for example, cured silver slurry, copper slurry, silver-coated copper slurry or cured conductive powder slurry. The conductive powder slurry is prepared by mixing 10 to 95% of the conductive powder having a particle size of less than 200 um, 1 to 40% of adhesive and 5 to 70% of solvent and mechanically grinding the mixture. The so-called conductive powder is powder having electrical conductivity, such as silver powder, copper powder, silver-coated copper powder, nickel powder or carbon powder. In another embodiment, in order to improve the electrical conductivity and thermal conductivity of the pin contacts 1111a, 1112a, 1113a, 1114a, 1115a and 1116a, it is chosen that the cured silver slurry, copper slurry, silver-coated copper slurry or cured conductive powder slurry is plated with a metal conductive layer including copper, and a protective layer is further formed on the metal conductive layer to improve the oxidation resistance and the surface mounting (SMT) solderability of the metal conductive layer. The material of the protective layer is nickel gold, nickel palladium gold, tin, silver or organic solder mask (OSP). In another embodiment, in order to improve the electrical conductivity and thermal conductivity of the pin contacts 1111a, 1112a, 1113a, 1114a, 1115a and 1116a, it may be chosen that a solder layer including nano silver or nano copper is formed on the cured silver slurry, copper slurry, silver-coated copper slurry or cured conductive powder slurry to facilitate the fixed connection of each pin of the light emitting source with the corresponding pin contacts 1111a, 1112a, 1113a, 1114a, 1115a and 1116a.

On the other hand, referring to FIG. 6, the rows 12 of patterned input voltage lines and the rows 13 of patterned grounded lines can be formed on the same plane by screen printing or inkjet printing after patterning. The materials of the rows 12 of the patterned input voltage lines including the parallel wires 121a and the rows 13 of the patterned grounded lines including the parallel wires 131a can be cured silver slurry, copper slurry, silver-coated copper slurry or cured conductive powder slurry. The preparation of the conductive powder slurry has been mentioned in the above description and is not repeated herein. In other words, the rows 12 of the patterned input voltage lines and the rows 13 of the patterned grounded lines include conductive powder particles made of a substance selected from a group consisting of copper, silver, nickel, silver-coated copper, and carbon and with particle size of less than 200 um. In addition, in order to improve the electrical conductivity and thermal conductivity of the rows 12 of the patterned input voltage lines and the rows 13 of the patterned grounded lines, it may be chosen that the cured silver slurry, copper slurry, silver-coated copper slurry or cured conductive powder slurry is plated with a metal conductive layer including copper.

FIG. 7 is a plan view schematically showing the arrangement of rows of the patterned input voltage lines, rows of the patterned grounded lines, and rows of the electrical pin connecting areas on a conductive substrate of a display device according to a seventh embodiment of the present invention. In the seventh embodiment, the rows 11a of the electrical pin connecting areas are disposed on the electrically insulating substrate 10. The arrangement of the electrical pin connecting areas 111a and the corresponding pin contacts of each of the rows 11a of the electrical pin connecting areas are the same as those mentioned in the first embodiment and will not be repeated herein. In the present embodiment, the electrically insulating substrate 10 has a plurality of transparent conductive layer regions that are separated and electrically isolated from each other by the trenches 60. The first transparent conductive layer region 61 of these transparent conductive layer regions is electrically connected to the data signal input pin contact 1115a of the electrical pin connecting area 111a and to the data signal output pin contact 1113 a of the neighboring electrical pin connecting area 111a of the same row 11a of electrical pin connecting areas. For example, the data signal input pin contact 1115a of the electrical pin connecting area 111a and the data signal output pin contact 1113a of the neighboring electrical pin connecting area 111a are formed on the first transparent conductive layer region 61. In addition, the second transparent conductive layer region 62 of the transparent conductive layer regions is electrically connected to the clock signal input pin contact 1114a of the electrical pin connecting area 111a and to the clock signal output pin contact 1112a of the neighboring electrical pin connecting area 111a of the same row 11a of electrical pin connecting areas. For example, the clock signal input pin contact 1114a of the electrical pin connecting area 111a and the clock signal output pin contact 1112a of the neighboring electrical pin connecting area 111a are formed on the second transparent conductive layer region 62. The wires of the row 12d of the patterned input voltage lines include a main wire 121d and a plurality of parallel connected wires 122d extending from the main wire 121d. The main wire 121d is extending in parallel with the neighboring row 11a of the electrical pin connecting areas and is disposed between two neighboring rows 11a of the electrical pin connecting areas while the parallel connected wires 122d extend toward the neighboring rows 11a of the electrical pin connecting areas, for example, along the direction perpendicular to neighboring rows 11a of the electrical pin connecting areas, and are respectively electrically connected to the input voltage pin contacts 1116a of the corresponding electrical pin connecting areas 111a in one of the neighboring rows 11a of the electrical pin connecting areas. The wires of the row 13d of patterned grounded lines include a main wire 131d and a plurality of parallel connected wires 132d extending from the main wire 131d. The main wire 131d is extending in parallel with the neighboring row 11a of the electrical pin connecting areas and is disposed between two neighboring rows 11a of the electrical pin connecting areas while the parallel connected wires 132d extend toward the neighboring rows 11a of the electrical pin connecting areas, for example, along the direction perpendicular to neighboring rows 11a of the electrical pin connecting areas, and are respectively electrically connected to the grounded pin contacts 1111a of the corresponding electrical pin connecting areas 111a in the neighboring row 11a of the electrical pin connecting areas.

In another aspect, the electrical connection shown in FIG. 7 can also be applied as the connection of each of the rows 11c of electrical pin connecting areas with the rows 12d of patterned input voltage lines and the rows 13d of patterned grounded lines as shown in FIG. 2D. In other words, two electrically isolated transparent conductive layer regions are utilized to respectively electrically connect the data signal input pin contact 1115c of the electrical pin connecting area 111c with the data signal output pin contact 1113c of the neighboring electrical pin connecting area 111c, and connect the clock signal input pin contact 1114c of the electrical pin connecting area 111c with the clock signal output pin contact 1112c of the neighboring electrical pin connecting area 111c, thereby increasing the transparency of the display device.

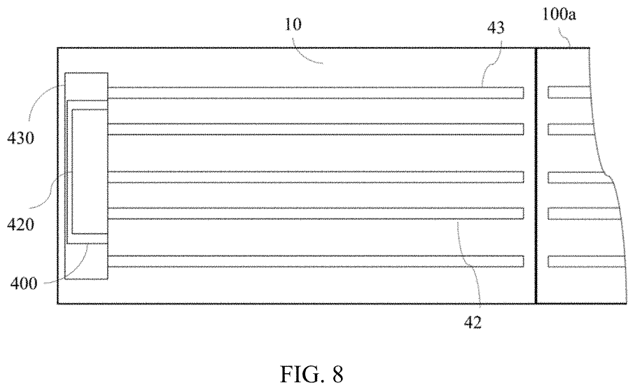

FIG. 8 is a plan view schematically showing rows of the patterned input voltage lines and rows of the grounded lines on a conductive substrate of a display device according to an eighth embodiment of the present invention. As shown in FIG. 8, the rows of the patterned input voltage lines 42 are commonly electrically connected to a first wire connecting region 420, the rows of the patterned grounded lines 43 are commonly electrically connected to a second wire connecting region 430, and the first wire connecting region 420 and the second wire connecting region 430 are disposed on the same side of the electrically insulating substrate 10 (the left side shown in FIG. 8), which is different from that the first wire connecting region 120 and the second wire connecting region 130 are disposed on the different sides of the electrically insulating substrate 10 in the first embodiment. In another embodiment, an insulating layer 400 can be disposed between the first wire connecting region 420 and the second wire connecting region 430, so that the first wire connecting region 420 and the second wire connecting region 430 are electrically isolated by the insulating layer 400, and the first wire connecting region 420 can be disposed above the second wire connecting region 430. The insulating layer 400 can be transparent. Thus, the joint of the other side (the right side shown in FIG. 8) of the electrically insulating substrate 10 on which the first wire connecting region 420 and the second wire connecting region 430 are not disposed with another conductive substrate 100a can be much facilitated. In FIG. 8, the size of the insulating layer 400, the first wire connecting region 420, and the second wire connecting region 430 is illustrated merely as examples, and the actual size depends on the number of required rows of the patterned input voltage lines 42 and the patterned grounded lines 43, the invention is not limited thereto.

The proposed conductive substrate of the display device according to the embodiments of the present invention has patterned conductive lines with high density, high electrical conductivity and high thermal conductivity. These patterned conductive lines include the rows of electrical pin connecting areas, the rows of patterned input voltage lines, and the rows of patterned grounded lines. The input voltage pin contacts of the electrical pin connecting areas in the same row are all connected to a parallel wire or a plurality of parallel wires of a neighboring row of the patterned input voltage lines, while the grounded pin contacts of the electrical pin connecting areas in the same row are all connected to a parallel wire or a plurality of parallel wires of a neighboring row of the patterned grounded lines. In addition, the input voltage pin contacts in the electrical pin connecting areas of two neighboring rows can be commonly connected to a row of patterned input voltage lines disposed between the two neighboring rows of the electrical pin connecting areas, while the grounded pin contacts in the electrical pin connecting areas of two neighboring rows can be commonly connected to a row of the patterned grounded lines disposed between the two neighboring rows of the electrical pin connecting areas. In this way, the proportion of the areas on the conductive substrate occupied by the conductive lines extending from the pin contacts of the rows of the electrical pin connecting areas to the peripheral of the conductive substrate is reduced, and which further increases the transparency of the display device. Therefore, the patterning process simplifies the manufacturing complexity of the conductive substrate of the display device.

At least one of the embodiments of the claimed invention with reference to the accompanying drawings have been described as above, it will be apparent to those skills that the invention is not limited to those precise embodiments, and that various modifications and variations can be made in the presently disclosed system without departing from the scope or spirit of the invention. Any above-mentioned patterned conductive layer refers to a layered structure with specific conductive line patterns formed on a substrate. The ways to form the patterned conductive layer includes, but is not limited to, screen printing, inkjet printing, filming, spraying, or laser etching after sputtering or evaporating. As long as the formed conductive layer has specific conductive line patterns, such as the electrical pin connecting areas or the patterned mesh with lattices, the formed conductive layer can be referred to as the patterned conductive layer of the present invention, and the present invention does not limit the formation manner. Thus, it is intended that the present disclosure cover modifications and variations of this disclosure provided they come within the scope of the appended claims and their equivalents. Specifically, one or more limitations recited throughout the specification can be combined in any level of details to the extent they are described to accomplish the conductive substrate of a display device.

What is claimed is:

1. A conductive substrate of a display device, comprising:
an electrically insulating substrate;
a plurality of rows of electrical pin connecting areas disposed on the electrically insulating substrate, each of the rows of the electrical pin connecting areas having a plurality of electrical pin connecting areas being electrically isolated and spaced from each other in a line, each of the electrical pin connecting areas including at least an input voltage pin contact and a grounded pin contact respectively served to electrically connect an input voltage pin and a grounded pin of a light emitting source;
a plurality of rows of patterned input voltage lines electrically connected with and spaced from each other and disposed on the electrically insulating substrate, wherein the rows of the patterned input voltage lines are respectively adjacent to the rows of the electrical pin connecting areas; and
a plurality of rows of patterned grounded lines electrically connected with and spaced from each other and disposed on the electrically insulating substrate, wherein the rows of the patterned grounded lines are respectively adjacent to the rows of the electrical pin connecting areas;
wherein two opposite sides of at least one of the rows of the patterned input voltage lines are respectively electrically connected with the input voltage pin contacts of the two neighboring rows of the electrical pin connecting areas while two opposite sides of at least one of the rows of the patterned grounded lines are respectively electrically connected with the grounded pin contacts of the two neighboring rows of the electrical pin connecting areas.

2. The conductive substrate of the display device of claim 1, wherein the input voltage pin contact and the grounded pin contact of each of the electrical pin connecting areas are diagonally disposed, the input voltage pin contacts of the two neighboring rows of the electrical pin connecting areas are located toward opposite directions, and the grounded pin contacts of the two neighboring rows of the electrical pin connecting areas are located toward opposite directions.

3. The conductive substrate of the display device of claim 1, wherein each of the rows of the patterned input voltage lines has a plurality of parallel connected wires respectively extending toward the neighboring rows of the electrical pin connecting areas and respectively connecting the input voltage pin contacts of the corresponding electrical pin connecting areas of the neighboring rows of the electrical connecting areas; or each of the rows of the patterned grounded lines has a plurality of parallel connected wires respectively extending toward the neighboring rows of the electrical pin connecting areas and respectively connecting the grounded pin contacts of the corresponding electrical pin connecting areas of the neighboring rows of the electrical connecting areas.

4. The conductive substrate of the display device of claim 1, wherein each of the rows of the patterned input voltage lines has at least one parallel wire extending in parallel with the row direction of the neighboring row of the electrical pin connecting areas and serially connecting the input voltage pin contacts of the electrical pin connecting areas of the neighboring row of the electrical pin connecting areas; or each of the rows of the patterned grounded lines has at least one parallel wire extending in parallel with the row direction of the neighboring row of the electrical pin connecting areas and serially connecting the grounded pin contacts of the electrical pin connecting areas of the neighboring row of the electrical pin connecting areas.

5. The conductive substrate of the display device of claim 1, wherein at least one of the rows of the patterned input voltage lines or at least one of the rows of the patterned grounded lines has a plurality of wires constituting a patterned mesh lines including a plurality of lattices.

6. The conductive substrate of the display device of claim 1, wherein the rows of the patterned input voltage lines and the rows of the patterned grounded lines are on the same plane and disposed in an interdigitated manner.

7. The conductive substrate of the display device of claim 1, wherein each of the electrical pin connecting areas further includes a data signal input pin contact, a data signal output pin contact, a clock signal input pin contact, and a clock signal output pin contact respectively used for electrical connection with a data signal input pin, a data signal output pin, a clock signal input pin, and a clock signal output pin of the light emitting source, wherein the data signal input pin contact and the clock signal input pin contact of one of the electrical pin connecting areas are respectively electrically connected to the data signal output pin contact and the clock signal output pin contact of the neighboring electrical pin connecting area.

8. The conductive substrate of the display device of claim 7, further comprising:
a plurality of transparent conductive layer regions disposed to be electrically isolated from each other on the electrically insulating substrate, wherein a first transparent conductive layer region of the transparent conductive layer regions electrically connects the data signal input pin contact of the electrical pin connecting area with the data signal output pin contact of the neighboring electrical pin connecting area, or a second transparent conductive layer region of the transparent conductive layer regions electrically connects the clock signal input pin contact of the electrical pin connecting area with the clock signal output pin contact of the neighboring electrical pin connecting area.

9. The conductive substrate of the display device of claim 8, wherein one of the rows of the patterned input voltage lines or one of the rows of the patterned grounded lines has a main wire and a plurality of parallel connected wires extending from the main wire, the main wire is disposed between the two neighboring rows of the electrical pin connecting areas while the parallel connected wires extend toward the neighboring row of the electrical pin connecting areas and respectively electrically connect the input voltage pin contacts or the grounded pin contacts of the corresponding electrical pin connecting areas in the neighboring row of the electrical pin connecting areas.

10. The conductive substrate of the display device of claim 1, wherein the input voltage pin and the grounded pin of the light emitting source are disposed on the same side of an emitting surface of the light emitting source.

11. The conductive substrate of the display device of claim 1, further comprising a plurality of transparent conductive layer regions disposed to be electrically isolated from each other on the electrically insulating substrate, wherein the input voltage pin contacts and the grounded pin contacts are respectively disposed on the transparent conductive layer regions and in touch with the transparent conductive layer regions.

12. The conductive substrate of the display device of claim 1, wherein the rows of the patterned input voltage lines are commonly electrically connected to a first wire connecting region, the rows of the patterned grounded lines are commonly electrically connected to a second wire connecting region, and the first wire connecting region and the second wire connecting region are disposed on the same side of the electrically insulating substrate.

13. The conductive substrate of the display device of claim 1, wherein the rows of the patterned input voltage lines and the rows of the patterned grounded lines include conductive powder particles made of a substance selected from a group consisting of copper, silver, nickel, silver-coated copper, and carbon and with particle size of less than 200 um.
